(19) United States
(12) Patent Application Publication
(10) Pub. No.: US 2026/0215304 A1
(43) Pub. Date: Jul. 23, 2026

(54) ELECTRONIC PACKAGE AND SUSBSTRATE STRUCTURE THEREOF

(71) Applicant: SILICONWARE PRECISION INDUSTRIES CO., LTD., Taichung City (TW)

(72) Inventor: Tsung-Lung SHEN, Taichung City (TW)

(73) Assignee: SILICONWARE PRECISION INDUSTRIES CO., LTD., Taichung City (TW)

(21) Appl. No.: 19/388,666

(22) Filed: Nov. 13, 2025

(30) Foreign Application Priority Data
Jan. 21, 2025 (TW) 114102553

(51) Int. Cl. H01L 23/498

(52) U.S. Cl. CPC H10W 70/65; H10W 70/685; H10W 90/701

(57) ABSTRACT

Provided are an electronic package and a substrate structure thereof, including a substrate body and a surface layer circuit, and the substrate body has a first side and a second side opposite to the first side. The first side is defined with a die-placement area and a peripheral area adjacent to the die-placement area. Conversely, the second side is defined with a projected die-placement area and a projected peripheral area adjacent to the projected die-placement area. A corner of the projected die-placement area corresponding to the projected peripheral area is further defined with a stress concentration area, and the stress concentration area is further defined with a stress extension line. Accordingly, an arrangement direction of the surface layer circuit formed on the second side of the substrate body does not overlap with the stress extension line, thereby preventing the surface circuitry from damaging.

### BACKGROUND

### 1. Technical Field

The present disclosure relates to a semiconductor structure, and more particularly, to an electronic package and a substrate structure thereof.

### 2. Description of Related Art

With the evolution of semiconductor packaging technology, different package types have been developed for semiconductor devices, wherein ball grid array (BGA), such as PBGA, EBGA, and FCBGA, is an advanced semiconductor packaging technology. The characteristic of BGA is that it uses a package substrate to place a semiconductor chip, and a plurality of solder balls arranged in a grid array are implanted on the back of the package substrate. This allows more input/output connections to be accommodated on the same unit area of the carrier to meet the needs of high integration of the semiconductor chips.

FIG. 1 shows a cross-sectional schematic view of a ball grid array package structure of the prior art. In this package structure, a semiconductor chip 110 is placed on one surface of a package substrate 100, and a plurality of solder balls 120 are planted in an array on the other surface of the package substrate 100 for subsequent connection to a circuit board.

Furthermore, with the rapid development of the semiconductor industry, and in response to the demand for multifunctional integration and high capacity in electronic products, larger-sized chips are often placed in the package structure. This not only tests the circuit design capabilities of the package substrate and the packaging process capabilities, but also causes excessive stress on the overall structure, and may even lead to abnormal reliability. Common problems include cracking of the green paint on the surface of the package substrate or breakage of the surface circuit on the side with solder balls.

To solve the aforementioned problems such as cracked green paint or broken surface circuits on the package substrate, it is often necessary to change the material of the package substrate or the appearance size of the semiconductor chip (e.g., change the thickness and size of the semiconductor chip). However, this change involves a major process change, which is usually unacceptable to customers.

Therefore, how to overcome the various problems of the above-mentioned prior art without changing the material and appearance size has become an urgent issue to be addressed.

### SUMMARY

In view of the above-mentioned deficiencies of the prior art, the present disclosure provides a substrate structure, which comprises: a substrate body having a first side and a second side opposite to the first side, wherein the first side is defined with a die-placement area and a peripheral area adjacent to the die-placement area, and the second side is defined with a projected die-placement area and a projected peripheral area adjacent to the projected die-placement area, and wherein the projected die-placement area corresponds to a vertical projected position of the die-placement area, and the projected peripheral area corresponds to a vertical projected position of the peripheral area, and wherein a corner of the projected peripheral area corresponding to the projected die-placement area is further defined with a stress concentration area, and the stress concentration area is further defined with a stress extension; and a surface layer circuit formed on the second side of the substrate body and including a conductive trace, wherein an arrangement direction of the conductive trace does not overlap with the stress extension line.

The present disclosure further provides an electronic package, which comprises: a substrate structure including: a substrate body having a first side and a second side opposite to the first side, wherein the first side is defined with a die-placement area and a peripheral area adjacent to the die-placement area, and the second side is defined with a projected die-placement area and a projected peripheral area adjacent to the projected die-placement area, and wherein the projected die-placement area corresponds to a vertical projected position of the die-placement area, and the projected peripheral area corresponds to a vertical projected position of the peripheral area, and wherein a corner of the projected peripheral area corresponding to the projected die-placement area is further defined with a stress concentration area, and the stress concentration area is further defined with a stress extension line; and a surface layer circuit formed on the second side of the substrate body and including a conductive trace, wherein an arrangement direction of the conductive trace does not overlap with the stress extension line; and an electronic element disposed in the die-placement area of the substrate structure.

In the aforementioned electronic package and the substrate structure thereof, the first side of the substrate body is a die-placement side for carrying an electronic element, and the second side of the substrate body is a ball-placement side for placing a plurality of conductive elements.

In the aforementioned electronic package and the substrate structure thereof, a length dimension and a width dimension of the stress concentration area are respectively widths of three conductive elements.

In the aforementioned electronic package and the substrate structure thereof, an angle between the stress extension line and one side of the adjacent projected die-placement area is 135 degrees.

In the aforementioned electronic package and the substrate structure thereof, a width of the conductive trace in the stress concentration area of the surface layer circuit is greater than a width of the conductive trace in other areas.

In the aforementioned electronic package and the substrate structure thereof, a width of the conductive trace in the stress concentration area of the surface circuit is twice a width of the conductive trace in other areas.

In the aforementioned electronic package and the substrate structure thereof, the substrate body includes a dielectric layer and a circuit layer bonded to the dielectric layer, and the surface layer circuit is electrically connected to the circuit layer.

In the aforementioned electronic package and the substrate structure thereof, the surface layer circuit further comprises a plurality of electrical connection pads connected to the conductive trace.

As can be seen from the above, in the electronic package and the substrate structure thereof of the present disclosure, the conductive trace of the surface layer circuit formed on the second side of the substrate body does not overlap with the stress extension line in the stress concentration area on the second side of the substrate body. Therefore, the width of the surface layer circuit located in the stress concentration area can be further widened to prevent the surface layer circuit from damaging.

### BRIEF DESCRIPTION OF THE DRAWINGS

FIG. 1 is a cross-sectional schematic view of a conventional ball grid array (BGA) package structure.

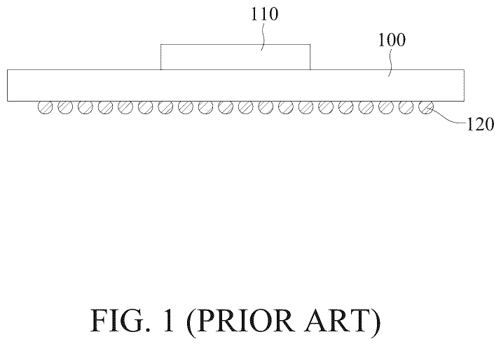

FIG. 2 is a cross-sectional schematic view of an electronic package and a substrate structure thereof according to the present disclosure.

FIG. 3 is a partial bottom schematic view of the substrate structure according to a first embodiment of the present disclosure.

FIG. 4 is a partial bottom schematic view of the substrate structure according to a second embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

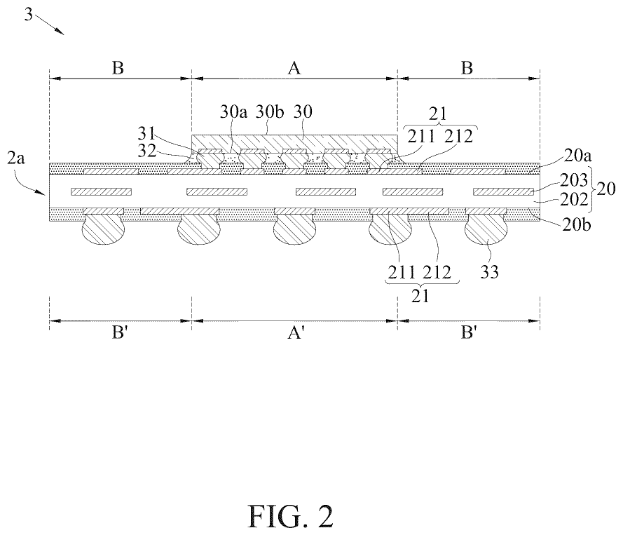

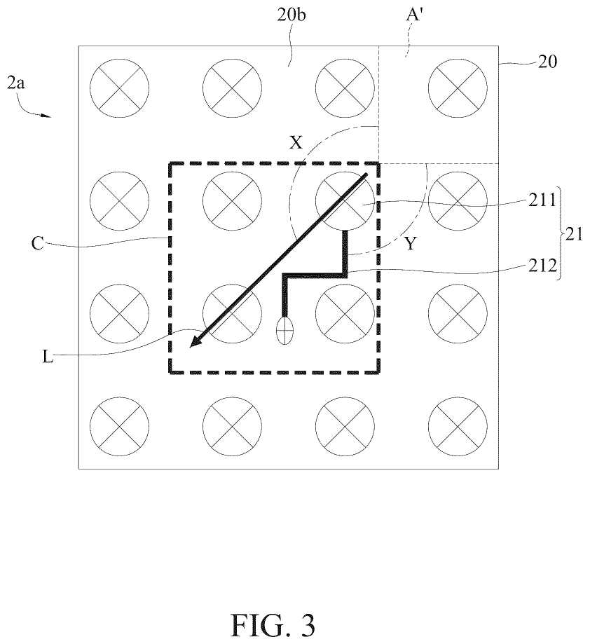

Referring to FIG. 2 and FIG. 3 simultaneously, FIG. 2 is a cross-sectional view of an electronic package and a substrate structure thereof according to the present disclosure, and FIG. 3 is a partial bottom view of the substrate structure according to the present disclosure.

An electronic package 3 comprises a substrate structure 2a and an electronic element 30 disposed on the substrate structure 2a.

The substrate structure 2a includes a substrate body 20 and a surface layer circuit 21 formed on the substrate body 20.

The substrate body 20 has a first side 20a and a second side 20b opposite to the first side 20a, and the first side 20a of the substrate body 20 can be served as a die-placement side for carrying an electronic element 30, and the second side 20b of the substrate body 20 can be served as a ball-placement side for connecting conductive elements 33.

The substrate body 20 is, for example, a package substrate with a core layer or a coreless package substrate, and the substrate body 20 includes a dielectric layer 202 and a circuit layer 203 bonded to the dielectric layer 202.

The surface layer circuit 21 is formed on the first side 20a and the second side 20b of the substrate body 20 and is electrically connected to the circuit layer 203. In one embodiment, the surface layer circuit 21 includes a plurality of interconnected electrical connection pads 211 and a conductive trace 212. One end of the conductive trace 212 is connected to one of the electrical connection pads 211, and the other end can be connected to a conductive blind via, thereby electrically connecting to the circuit layer 203 through the conductive blind via.

The circuit layer 203 and the surface layer circuit 21 can be formed, for example, by a redistribution layer (RDL) fabrication method. The circuit layer 203 and the surface layer circuit 21 are made of copper, and the dielectric layer 202 is made of dielectric materials such as polybenzoxazole (PBO), polyimide (PI), or prepreg (PP).

A first side 20a of the substrate body 20 is defined with a die-placement area A and a peripheral area B adjacent to the die-placement area A, wherein the surface layer circuit 21 formed on the first side 20a of the substrate body 20 can span the die-placement area A and the peripheral area B. The die-placement area A is configured to connect the electronic element, and the peripheral area B is disposed around the die-placement area A and can be configured to place passive elements or heat sinks.

A projected die-placement area A′ and a projected peripheral area B′ adjacent to the projected die-placement area A′ are defined on the second side 20b of the substrate body 20. The projected die-placement area A′ corresponds to the vertical projected position of the die-placement area A, and the projected peripheral area B′ corresponds to the vertical projected position of the peripheral area B. The surface layer circuit 21 formed on the second side 20b of the substrate body 20 can span the projected die-placement area A′ and the projected peripheral area B′.

The electronic element 30 is an active element such as a semiconductor chip. In one embodiment, the electronic element 30 has an active surface 30a and an inactive surface 30b opposite to the active surface 30a, and the active surface 30a has a plurality of electrode pads. Accordingly, the electronic element 30 is electrically connected to the electrical connection pads 211 of the surface layer circuit 21 of the first side 20a of the substrate body 20 via a plurality of conductive bumps 31 containing solder material in a flip-chip manner, and then the conductive bumps 31 are covered with an underfill 32.

In addition, the electronic package 3 further comprises a plurality of conductive elements 33 disposed on the substrate structure 2a (the second side 20b of the substrate body 20).

In one embodiment, the conductive elements 33 are, for example, solder balls. The conductive elements 33 are disposed on the electrical connection pads 211 of the surface layer circuit 21 on the second side 20b of the substrate body 20, allowing the electronic package 3 to be electrically connected to an external device (e.g., a circuit board) via the plurality of conductive elements 33.

Further, a corner of the projected die-placement area A′ corresponding to the projected periphery area B′ of the second side 20b of the substrate body 20 is further defined with a stress concentration area C. The stress concentration area C is a concentrated area where the substrate body 20 is subjected to stress during the packaging process, and the length and width thereof are each approximately the width of three conductive elements 33 (solder balls).

Furthermore, a stress extension line L is further defined within the stress concentration area C. This stress extension line L is a direction of extension of the stress concentration region C where greater stress is present. The surface layer circuit 21 (conductive trace 212) formed on the second side 20b of the substrate body 20 is not arranged in a direction that overlaps with the stress extension line L, in order to prevent the surface layer circuit 21 on the second side 20b of the substrate body 20 from cracking.

In one embodiment, as shown in FIG. 3, the angle X between the stress extension line L and one side of the adjacent projected die-placement area A′ is approximately 135 degrees, while the angle between the conductive trace 212 of the surface layer circuit 21 formed on the second side 20b of the substrate body 20 and one side of the adjacent projected die-placement area A′ is approximately 90 degrees. Accordingly, the two angles are different to avoid overlap.

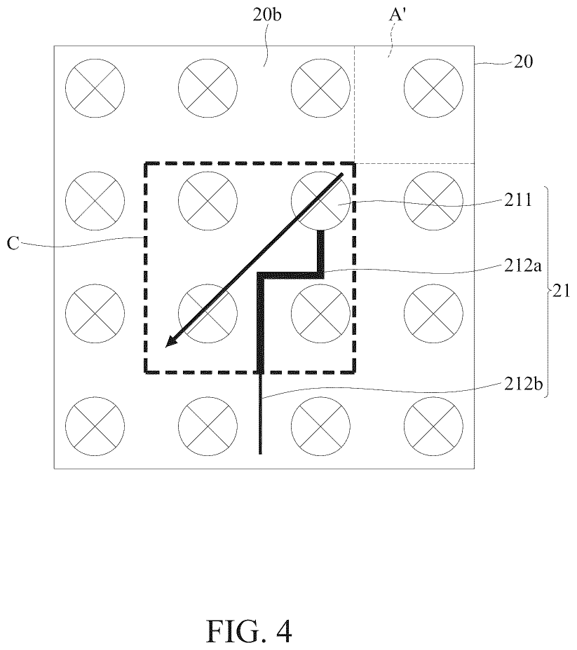

In another embodiment, as shown in FIG. 4, the width of the conductive trace 212a in the stress concentration area C of the surface layer circuit 21 formed on the second side 20b of the substrate body 20 is greater than the width of the conductive trace 212b in other areas. For example, the width of the conductive trace 212a in the stress concentration area C of the surface layer circuit 21 is approximately twice the width of the conductive trace 212b in other areas, in order to prevent the surface layer circuit 21 from cracking.

To sum up, in the electronic package and the substrate structure thereof of the present disclosure, the conductive trace of the surface layer circuit formed on the second side of the substrate body does not overlap with the stress extension line in the stress concentration area on the second side of the substrate body. Therefore, the width of the surface layer circuit located in the stress concentration area can be further widened to prevent the surface layer circuit from damaging.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
a substrate body having a first side and a second side opposite to the first side, wherein the first side is defined with a die-placement area and a peripheral area adjacent to the die-placement area, and the second side is defined with a projected die-placement area and a projected peripheral area adjacent to the projected die-placement area, and wherein the projected die-placement area corresponds to a vertical projected position of the die-placement area, and the projected peripheral area corresponds to a vertical projected position of the peripheral area, and wherein a corner of the projected peripheral area corresponding to the projected die-placement area is further defined with a stress concentration area, and the stress concentration area is further defined with a stress extension line; and
a surface layer circuit formed on the second side of the substrate body and including a conductive trace, wherein an arrangement direction of the conductive trace does not overlap with the stress extension line.

2. The substrate structure of claim 1, wherein the first side of the substrate body is a die-placement side for carrying an electronic element, and the second side of the substrate body is a ball-placement side for placing a plurality of conductive elements.

3. The substrate structure of claim 2, wherein a length dimension and a width dimension of the stress concentration area are respectively widths of three conductive elements.

4. The substrate structure of claim 1, wherein an angle between the stress extension line and one side of the adjacent projected die-placement area is 135 degrees.

5. The substrate structure of claim 1, wherein a width of the conductive trace in the stress concentration area of the surface layer circuit is greater than a width of the conductive trace in other areas.

6. The substrate structure of claim 1, wherein a width of the conductive trace in the stress concentration area of the surface circuit is twice a width of the conductive trace in other areas.

7. The substrate structure of claim 1, wherein the substrate body includes a dielectric layer and a circuit layer bonded to the dielectric layer, and the surface layer circuit is electrically connected to the circuit layer.

8. The substrate structure of claim 1, wherein the surface layer circuit further comprises a plurality of electrical connection pads connected to the conductive trace.

9. An electronic package, comprising:
a substrate structure, including:
a substrate body having a first side and a second side opposite to the first side, wherein the first side is defined with a die-placement area and a peripheral area adjacent to the die-placement area, and the second side is defined with a projected die-placement area and a projected peripheral area adjacent to the projected die-placement area, and wherein the projected die-placement area corresponds to a vertical projected position of the die-placement area, and the projected peripheral area corresponds to a vertical projected position of the peripheral area, and wherein a corner of the projected peripheral area corresponding to the projected die-placement area is further defined with a stress concentration, and the stress concentration area is further defined with a stress extension line; and
a surface layer circuit formed on the second side of the substrate body and including a conductive trace, wherein an arrangement direction of the conductive trace does not overlap with the stress extension line; and
an electronic element disposed in the die-placement area of the substrate structure.

10. The electronic package of claim 9, wherein the first side of the substrate body is a die-placement side for carrying an electronic element, and the second side of the substrate body is a ball-placement side for placing a plurality of conductive elements.

11. The electronic package of claim 10, wherein a length dimension and a width dimension of the stress concentration area are respectively widths of three conductive elements.

12. The electronic package of claim 9, wherein an angle between the stress extension line and one side of the adjacent projected die-placement area is 135 degrees.

13. The electronic package of claim 9, wherein a width of the conductive trace in the stress concentration area of the surface layer circuit is greater than a width of the conductive trace in other areas.

14. The electronic package of claim 9, wherein a width of the conductive trace in the stress concentration area of the surface circuit is twice a width of the conductive trace in other areas.

15. The electronic package of claim 9, wherein the substrate body includes a dielectric layer and a circuit layer bonded to the dielectric layer, and the surface layer circuit is electrically connected to the circuit layer.

16. The electronic package of claim 9, wherein the surface layer circuit further comprises a plurality of electrical connection pads connected to the conductive trace.
